(19) United States
(12) Patent Application Publication
(10) Pub. No.: US 2021/0200081 A1
(43) Pub. Date: Jul. 1, 2021

(54) PATTERN FORMATION METHODS

(71) Applicants: Rohm and Haas Electronic Materials LLC, Marlborough, MA (US); Rohm and Haas Electronic Materials Korea Ltd., Cheonan (KR)

(72) Inventors: Cheng-Bai XU, Southborough, MA (US); Cong Liu, Shrewsbury, MA (US); James Field Cameron, Brookline, MA (US); Jae-Bong Lim, Chung-Nam (KR); Xisen Hou, Lebanon, NH (US); Jae-Hwan Sim, Kyonggi-do (KR)

(21) Appl. No.: 17/110,441

(22) Filed: Dec. 3, 2020

Related U.S. Application Data
(60) Provisional application No. 62/956,200, filed on Dec. 31, 2019.

(51) Int. Cl. G03F 7/00; G03F 7/039; G03F 7/038

(52) U.S. Cl. CPC G03F 7/0005; G03F 7/0382; G03F 7/0392

(57) ABSTRACT

Pattern formation methods comprise: (a) forming an underlayer on a substrate, wherein the underlayer has a thickness of 5 microns or more; (b) forming a photoresist layer on the underlayer, wherein the photoresist layer is formed from a photoresist composition comprising a silicon-containing polymer, a photoacid generator, and a solvent, wherein the silicon-containing polymer comprises as polymerized units a monomer of formula (I):

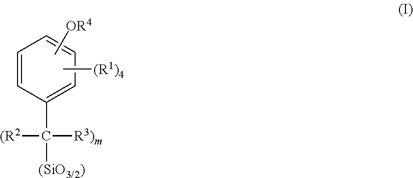

wherein: R¹ is independently chosen from H, F, OH, C1-C6 alkyl, C1-C6 haloalkyl, C1-C6 hydroxy-haloalkyl, C1-C6 alkoxy, or C1-C6 haloalkoxy; R² is independently chosen from H or F; R³ is independently chosen from H, F, CH₃, CF₃, CHF₂, or CH₂F; comprises an acid cleavable group; and m is an integer from 0 to 2; (c) patternwise exposing the photoresist layer to activating radiation; (d) developing the exposed photoresist layer to form a photoresist pattern; and (f) transferring the pattern of the photoresist pattern into the underlayer using the photoresist pattern as an etch mask. The invention has particular applicability in the formation of three-dimensional patterns such as staircase patterns used in the formation of semiconductor devices.

### BACKGROUND OF THE INVENTION

The invention relates generally to the manufacture of semiconductor devices. More specifically, this invention relates to the formation of three-dimensional patterns such as staircase patterns used in the manufacture of semiconductor devices.

A product area that has become of increased focus in the semiconductor industry is NAND flash memory. The solid-state, non-volatile nature of these devices make them an attractive option for replacement of magnetic storage media such as hard disk drives. To improve their commercial viability, further reductions in per-bit cost of these devices would be desired. The semiconductor manufacturing industry has conventionally reduced per-bit cost by increasing device integration density. Reducing NAND flash device geometries, however, has become increasingly difficult given limitations in current lithographic processes, materials, and process tools. In an effort to address these limitations, changes in device architecture to achieve greater storage capacity have been developed. One such development in device architecture makes use of multiple layers of memory cells to form stacked three-dimensional (3D) structures for NAND device applications. 3D NAND flash devices are typically denser, faster, and less expensive than traditional 2D planar NAND devices.

Known 3D NAND devices use vertical channel and vertical gate architectures. A stepped structure in the form of a “staircase” pattern is used to form an electrical connection between memory cells and bit lines or word lines. In forming staircase patterns for 3D NAND devices, a multilayered stack of alternating silicon oxide (SiO) and silicon nitride (SiN) layers is typically formed on a silicon substrate by chemical vapor deposition. In a conventional process, a thick (e.g., 5-12 micron) organic photoresist layer designed for deep-UV (KrF, 248 nm) exposure is formed over the SiO/SiN stack. A thick resist layer is desired for its ability to be used for a number of process cycles in forming the staircase pattern. In the conventional staircase formation process, the photoresist layer is patternwise exposed to activating radiation and developed to expose a region of the underlying SiO layer that corresponds with the landing (bottom) of the staircase pattern to be formed. The exposed SiO layer and immediately underlying SiN layer are next sequentially etched using the photoresist layer as an etch mask. The photoresist layer is next subjected to a trim-etch step to expose a region of the immediately underlying SiO layer corresponding with the first step of the staircase pattern. The series of resist trim-etch, SiO etch, and SiN etch steps are repeated until the staircase pattern is formed.

As 3D-NAND architectures move from 64 vertical layers to 96 layers, 128 layers, and beyond, a need for thicker photoresist layers has arisen. The use of thick resist layers in KrF lithography for printing micron-scale features is, however, associated with unique technical challenges. For example, patterning a thick resist layer with acceptable pattern fidelity requires sufficient transmittance through the layer at exposure wavelength to allow incident radiation to reach the bottom of the layer. The maximum usable thickness for the photoresist layer (and maximum number of trim/etch cycles) is thus limited by absorption of the resist layer during exposure. The amount of radiation passing through the resist layer is effectively reduced due to absorption effects as it passes through the depth of the layer. It is important that resist layer thickness be maintained within a range allowing for sufficient transmission of exposure radiation to the bottom of the layer. While additional photoresist layers can be formed and imaged once the original photoresist layer has been consumed, the use of multiple photoresist layers is not preferred due to reduced process throughput and possible photomask alignment errors.

Further challenges associated with the use of a thick photoresist resist layer in staircase pattern formation can result from the repeated etching steps required. Exposing the resist layer to numerous etching steps can adversely impact structural uniformity of and lead to the formation of rough surfaces and voids in the resist layer. Such issues are believed to result from unintended cleavage of acid-labile groups on the photoresist polymer during processing. These effects can result in poor pattern fidelity and adversely impact electrical characteristics of the formed devices.

Another consideration impacting resist layer thickness is etch selectivity of the resist layer with respect to underlying layers to be etched. Typically, thick KrF organic photoresists used in forming staircase patterns have a relatively poor etch selectivity, thus requiring a greater resist thickness to withstand etching steps for a given number of layers of the SiO/SiN stack. It would therefore be desired for the photoresist layer to have a relatively low etch rate versus that of underlying layers to be etched.

A further challenge in processing thick photoresist layers concerns critical dimension uniformity (CDU). CDU is an indicator of process window across the wafer for the resist imaging process. A relatively better CDU is indicative of a larger process window, which would allow for greater deviation from specification in exposure conditions (e.g., exposure dose and focus) without adversely impacting CD.

There is a need in the art for pattern formation methods useful in the manufacture of semiconductor devices that address one or more problems associated with the state of the art.

### SUMMARY OF THE INVENTION

In accordance with a first aspect of the invention, pattern formation methods are provided. The methods comprise: (a) forming an underlayer on a substrate, wherein the underlayer has a thickness of 5 microns or more; (b) forming a photoresist layer on the underlayer, wherein the photoresist layer is formed from a photoresist composition comprising a silicon-containing polymer, a photoacid generator, and a solvent, wherein the silicon-containing polymer comprises as polymerized units a monomer of formula (I):

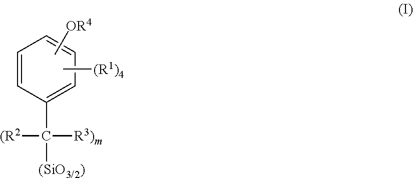

wherein: R¹ is independently chosen from H, F, OH, C1-C6 alkyl, C1-C6 haloalkyl, C1-C6 hydroxy-haloalkyl, C1-C6 alkoxy, or C1-C6 haloalkoxy; R² is independently chosen from H or F; R³ is independently chosen from H, F, CH₃, CF₃, CHF₂, or CH₂F; R⁴ comprises an acid cleavable group; and m is an integer from 0 to 2; (c) patternwise exposing the photoresist layer to activating radiation; (d) developing the exposed photoresist layer to form a photoresist pattern; and (f) transferring the pattern of the photoresist pattern into the underlayer using the photoresist pattern as an etch mask. The methods find particular applicability in the manufacture of semiconductor devices and, in particular, to the formation of staircase patterns.

In accordance with a further aspect of the invention, (a) forming the underlayer on the substrate comprises: (a1) coating an organic underlayer composition on the substrate; (a2) drying the coated underlayer composition; and (a3) repeating (a1) and (a2) one or more additional times to form the underlayer.

In accordance with a further aspect of the invention, the pattern formation method further comprises, in sequence: (g) after transferring the pattern of the photoresist pattern into the underlayer, transferring the pattern of the underlayer into the substrate to form a first etched substrate region; (h) trimming the underlayer to expose a surface of the substrate adjacent to the first etched substrate region; and (i) transferring the pattern of the trimmed underlayer into the exposed surface of the substrate while simultaneously further etching the first etched substrate region.

In accordance with a further aspect of the invention, the methods form a staircase pattern comprising a plurality of stairs in the substrate.

The terminology used herein is for the purpose of describing particular embodiments only and is not intended to be limiting of the invention. The singular forms “a”, “an”, and “the” are intended to include singular and plural forms, unless the context indicates otherwise.

The term “polymer” includes oligomers, dimers, trimers, tetramers, and the like, and refers to both homopolymers and copolymers. Copolymers include two, three, four or more structurally distinct repeating units. The term “alkyl” refers to linear, branched, and cyclic alkyl. The terms “halogen” and “halo” include fluorine, chlorine, bromine, and iodine. Thus, the term “halogenated” refers to fluorinated, chlorinated, brominated, and iodinated. “Fluoroalkyl” refers to both partially fluorinated and fully (perfluorinated) alkyl. The terms “acid-labile group”, “acid-cleavable group”, and “leaving group” are used interchangeably.

“Substituted” refers to a group (e.g., aryl or alkyl) having one or more of its hydrogen atoms replaced with one or more substituents chosen, for example, from halogen, hydroxy, C1-C6 alkyl, C1-C6 haloalkyl, C1-C6 alkoxy, C1-C6 haloalkoxy, or C5-C15 aryl.

All amounts are percent by weight (wt %) and all ratios are by weight, unless otherwise noted. All numerical ranges are inclusive and combinable in any order, except where it is obvious that such numerical ranges are constrained to add up to 100%.

Weight average molecular weight (Mw), number average molecular weight (Mn), and polydispersity index (PDI=Mw/Mn) as used herein are determined by GPC versus polystyrene standards.

When an element such as a layer, region or substrate is referred to as being “on” another element, it may be directly on the other element or intervening elements may be present.

### BRIEF DESCRIPTION OF THE DRAWINGS

The present invention will be described with reference to the following drawing, in which like reference numerals denote like features, and in which:

FIGS. 1A-1L illustrate a process flow for lithographically forming a staircase pattern using a silicon-containing photoresist layer and underlayer in accordance with the invention;

FIG. 2 is a SEM photomicrograph showing in cross-section a trench pattern formed using a conventional thick photoresist layer; and

FIG. 3 is a SEM photomicrograph showing in cross-section a trench pattern formed using a silicon-containing photoresist layer and underlayer in accordance with the invention.

### DETAILED DESCRIPTION

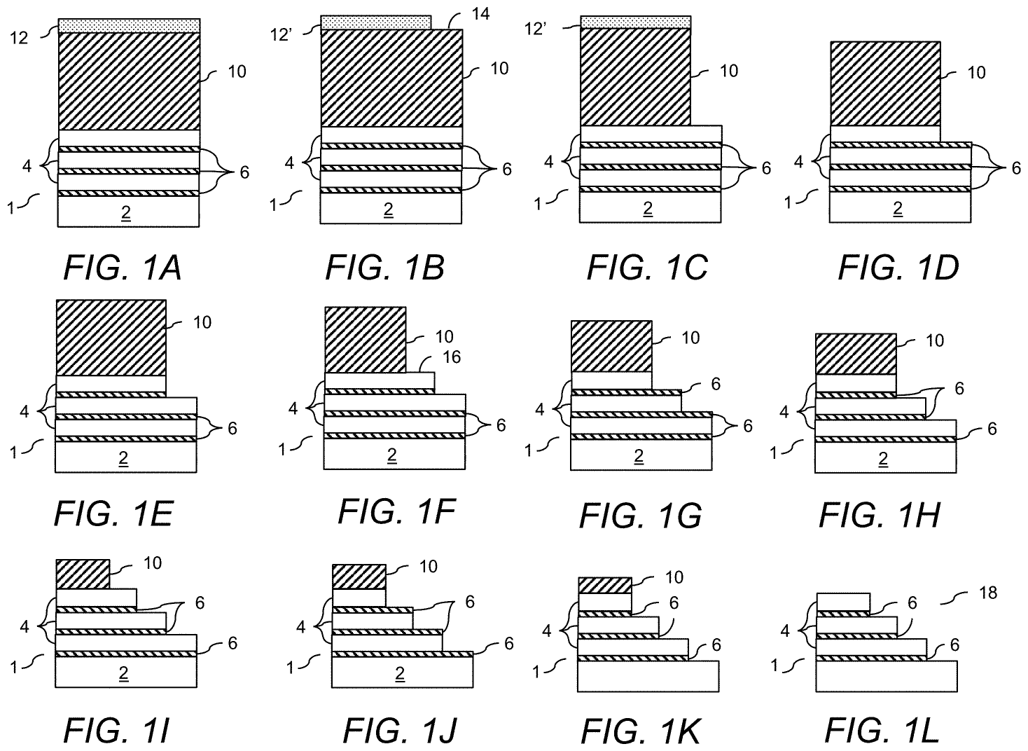

Pattern formation methods of the invention will now be described with reference to FIGS. 1A-1L, which illustrate an exemplary process flow for pattern formation methods in accordance with the invention. While the exemplified process flow describes a patterning process in which a staircase pattern is formed on a substrate, it should be clear that the methods can be used to form other pattern types.

FIG. 1A depicts in cross-section a substrate 1 which may include various layers and features. The substrate can be of a material such as a semiconductor, such as silicon or a compound semiconductor (e.g., III-V or II-VI), glass, quartz, ceramic, copper, and the like. Typically, the substrate is a semiconductor wafer, such as single crystal silicon or compound semiconductor wafer having a diameter, for example, of 150 mm, 200 mm, 300 mm, or other dimensions useful in semiconductor manufacture, and may have one or more layers and patterned features formed on a surface thereof. One or more layers to be patterned may be provided over the substrate. Optionally, the underlying base substrate material itself may be patterned, for example, when it is desired to form trenches in the substrate material. The layers on the substrate may include, for example, one or more conductive layers such as layers of aluminum, copper, molybdenum, tantalum, titanium, tungsten, alloys, nitrides or silicides of such metals, doped amorphous silicon or doped polysilicon, one or more dielectric layers such as layers of silicon oxide, silicon nitride, silicon oxynitride, or metal oxides, semiconductor layers, such as single-crystal silicon, and combinations thereof. The layers can be formed by various techniques, for example, chemical vapor deposition (CVD) such as plasma-enhanced CVD (PECVD), low-pressure CVD (LPCVD) or atomic layer deposition (ALD), physical vapor deposition (PVD) such as sputtering or evaporation, or electroplating. The particular thickness of the layers will vary depending on the materials and particular function of the layers.

In the exemplified method, substrate 1 includes base layer 2 and a multilayered stack of alternating silicon oxide (SiO) layers 4 and silicon nitride (SiN) layers 6 on the base layer. The silicon oxide and silicon nitride layers can be stoichiometric or no-stoichiometric materials, and are typically formed by PECVD or LPCVD.

An underlayer 10 is formed over the multilayered stack. The underlayer is formed from an underlayer composition comprising a polymer, a crosslinker, and a solvent. The underlayer polymer preferably an organic polymer having properties of good etch selectivity with respect to an overcoated silicon-containing photoresist layer 12, high etch-resistance during SiO and SiN layer etching, low reflectivity and high absorption at the photoresist exposure wavelength, and resistance to the overcoated photoresist composition (no or minimal intermixing). The underlayer polymer is preferably an aromatic polymer, and more preferably, a phenolic polymer, for example, a poly(vinylphenol). Also preferred is where the underlying polymer composition is a crosslinking composition that contains an acid generator, for example, a thermal acid generator (TAG) compound and/or a photoacid generator (PAG) compound, and preferably a separate crosslinker component such as an amine-based material, for example, a melamine or benzoguanamine resin. The underlayer composition should be non-photoimageable and free of free acids.

The underlayer composition can be applied to the substrate by spin-coating, dipping, roller-coating or other conventional coating technique, with spin-coating being typical. For spin-coating, the solids content of the coating solution can be adjusted to provide a desired film thickness based upon the specific coating equipment utilized, the viscosity of the solution, the speed of the coating tool, and the amount of time allowed for spinning. The thickness of the underlayer is 5 microns or more, preferably 10 microns or more, or 15 microns or more. The underlayer composition can next be cured by thermal treatment to remove solvent and, for crosslinkable compositions, to promote crosslinking of the layer. The thermal treatment can be conducted on a hotplate or in an oven. The temperature and time will depend, for example, on the particular material of the underlayer and thickness. Typical thermal treatment is conducted at a temperature of from 150 to 250° C., and a time of from 1 to 2 minutes. The underlayer composition can be applied in a single application or can be applied as a multilayered coating depending on desired film thickness. If a multilayered coating is desired, a first layer of the underlayer composition can applied on the substrate, and this coating/drying sequence repeated one or more additional times to form the underlayer.

A silicon-containing photoresist composition as described below is next coated over the underlayer 10 to form photoresist layer 12. The photoresist composition can be applied to the substrate by spin-coating, dipping, roller-coating or other conventional coating technique. Of these, spin-coating is typical. For spin-coating, the solids content of the coating solution can be adjusted to provide a desired film thickness based upon the specific coating equipment utilized, the viscosity of the solution, the speed of the coating tool, and the amount of time allowed for spinning. A typical thickness for the photoresist layer 12 is from 0.1 to 2 microns. The photoresist layer 12 is typically next softbaked to minimize the solvent content in the layer, thereby forming a tack-free coating and improving adhesion of the layer to the substrate. The softbake can be conducted on a hotplate or in an oven, with a hotplate being typical. The softbake temperature and time will depend, for example, on the particular material of the photoresist and thickness. Typical softbakes are conducted at a temperature of from about 90 to 150 ° C., and a time of from about 30 to 90 seconds.

The photoresist layer 12 is next exposed to activating radiation through a photomask to create a difference in solubility between exposed and unexposed regions. References herein to exposing a photoresist layer to radiation that is activating for the layer indicates that the radiation is capable of forming a latent image in the photoresist composition. The photomask has optically transparent and optically opaque regions corresponding to regions of the resist layer to be exposed and unexposed, respectively, by the activating radiation. The exposure wavelength is preferably deep-UV (248 nm) or an EUV wavelength (e.g., 13.5 nm), but may be used with other radiation sources. The exposure energy is typically from about 1 to 150 mJ/cm², depending, for example, on the exposure tool and the components of the photoresist composition. Following exposure of the photoresist layer 12, a post-exposure bake (PEB) is typically performed. The PEB can be conducted, for example, on a hotplate or in an oven. Conditions for the PEB will depend, for example, on the particular photoresist composition and layer thickness. The PEB is typically conducted at a temperature of from about 70 to 160° C., and a time of from about 30 to 90 seconds. A latent image defined by the boundary between polarity-switched and unswitched regions (corresponding to exposed and unexposed regions, respectively) is thereby formed.

The photoresist layer 12 is next developed to remove exposed regions of the layer, leaving unexposed regions forming resist pattern 12′ as shown in FIG. 1B. This exposes upper surface 14 of the underlayer, which exposed region corresponds to the landing (bottom) of the staircase pattern to be formed. The developer is typically an aqueous alkaline developer, for example, an aqueous quaternary ammonium hydroxide solution, for example, a tetra-alkyl ammonium hydroxide solution such as a tetramethylammonium hydroxide (TMAH) solution, typically 0.26N (2.38 wt %) TMAH.

The underlayer 10 is next dry-etched etched using the photoresist layer as an etch mask, with the resulting structure being shown in FIG. 1C. The resist pattern 12′ and underlayer 10 of FIG. 1C are then used as an etch-mask for pattern transfer into the uppermost SiO layer 4, with the resulting structure being shown in FIG. 1D. The original thickness of the silicon-containing resist 12 can be selected such that it is completely consumed during the underlayer etching process. If there is residual silicon-containing resist remaining after etching the underlayer, it may be removed in a separate etching step. The portion of the uppermost SiN layer 6 exposed after the oxide etch is next dry-etched using the underlayer 10 as an etch-mask (FIG. 1E). The underlayer is next subjected to a trim-etch step (FIG. 1F) to expose a fresh surface 16 of the immediately underlying SiO layer corresponding to a first step of the staircase pattern to be formed. The sequence of trim-etch (FIGS. 1F, 1I), SiO etch (FIGS. 1G, 1J), and SiN etch (FIGS. 1H, 1K) steps are repeated until the staircase pattern is formed. The remaining underlayer 10 can then be removed by an etching process as shown in FIG. 1L to provide staircase pattern 18.

While FIG. 1 illustrates fabrication of a limited number of steps, it should be clear that the described process can be applied to staircase patterns containing any number of steps. In the event that underlayer 10 becomes fully consumed, a new underlayer and silicon-containing resist can be formed and the process repeated.

### Photoresist Compositions

Photoresist compositions useful in the methods of the invention comprise a silicon-containing polymer, a photoacid generator, a solvent, and may include additional, optional components. The silicon-containing polymer is a hybrid organic-inorganic material, and can be a homopolymer, but is more typically a copolymer formed from two, three, or more structurally different monomers. The polymer comprises as polymerized units a monomer of formula (I):

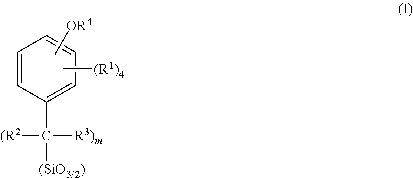

wherein: R¹ is independently chosen from H, F, OH, C1-C6 alkyl, C1-C6 haloalkyl, C1-C6 hydroxy-haloalkyl, C1-C6 alkoxy, or C1-C6 haloalkoxy; R² is independently chosen from H or F; R³ is independently chosen from H, F, CH₃, CF₃, CHF₂, or CH₂F; R⁴ comprises an acid cleavable group; and m is an integer from 0 to 2. The polymerized units of formula (I) may suitably be present in the polymer in an amount of from 10 to 100 mol %, based on total polymerized units of the polymer.

Suitable monomers of formula (I) include, for example, the following:

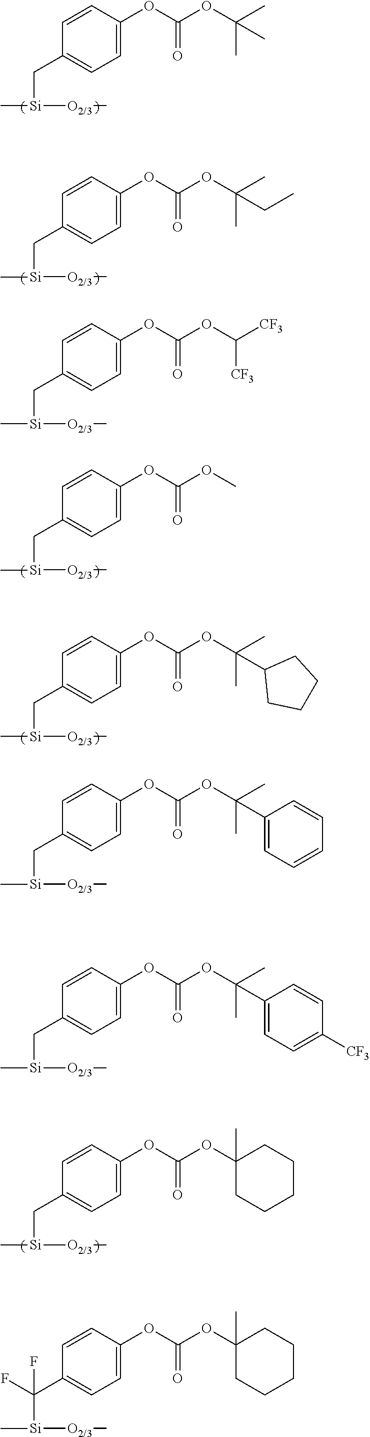

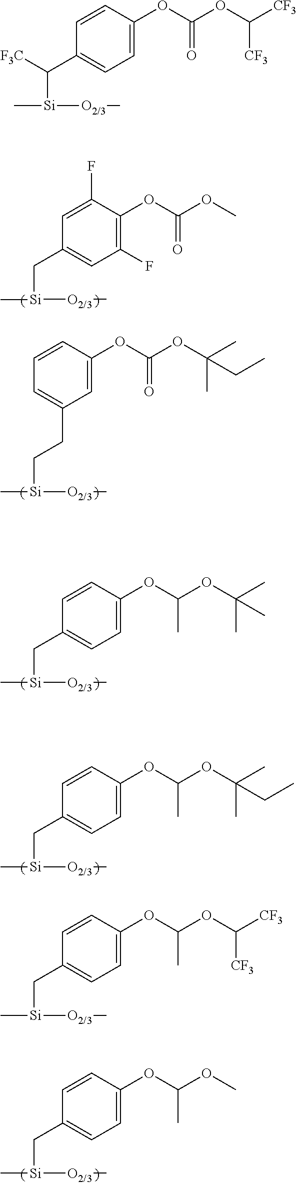

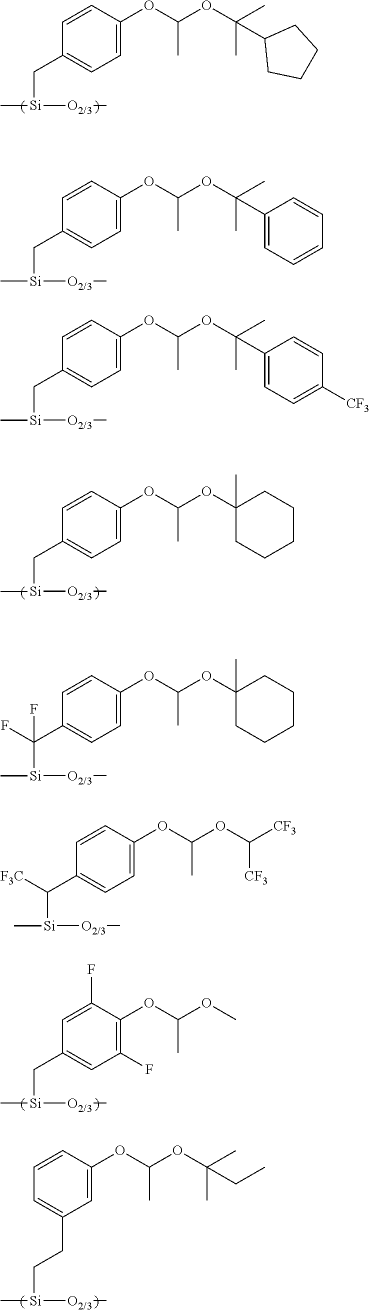

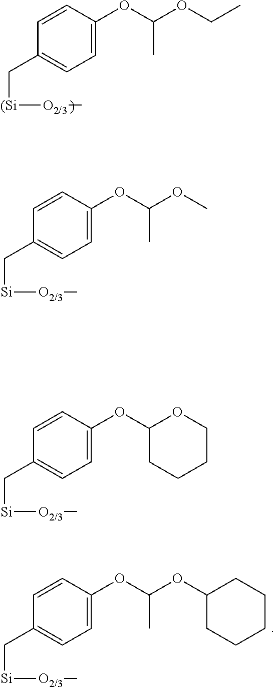

The polymer may further include one or more additional, distinct polymerized units. Particularly suitable are polymerized units of a monomer of formula (II):

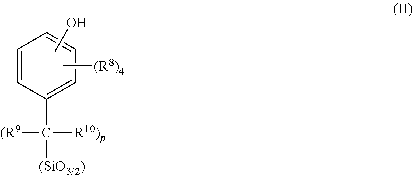

wherein: R⁸ is independently chosen from H, F, OH, C1-C6 alkyl, C1-C6 haloalkyl, C1-C6 hydroxy-haloalkyl, C1-C6 alkoxy, or C1-C6 haloalkoxy; R⁹ is independently chosen from H or F; R¹⁰ is independently chosen from H, F, CH₃, CF₃, CHF₂, or CH₂F; and p is an integer from 0 to 2. The polymerized units of formula (II) may suitably be present in the polymer in an amount of from 0 to 70 mol %, based on total polymerized units of the polymer.

Further suitable additional units for the polymer are polymerized units of a monomer of formula (III):

(R¹¹SiO_{3/2}) (III)

wherein: R¹² is chosen from C1-C12 alkyl, C2-C6 alkenyl, vinyl, each of which may be substituted or unsubstituted,

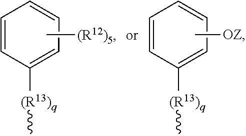

wherein: each R¹² is independently chosen from H, F, C1-C6 alkyl, C1-C6 alkoxy, C1-C6 haloalkyl, C1-C6 hydroxy-haloalkyl, C1-C6 haloalkoxy; R¹³ is C1-C5 alkylene; Z is chosen from —S(O₂)R¹⁴, wherein R¹⁴ is chosen from C1-C6 alky or C6-C15 aryl; q is 0 or 1; and the wavy line is a covalent bond to a Si atom in formula (III). The polymerized units of formula (III) are typically present in the polymer in an amount of from 0 to 20 mol %, based on total polymerized units of the polymer.

The silicon-containing polymer preferably comprise one or more groups chosen from formulas (IV), (V), (VI), or (VII):

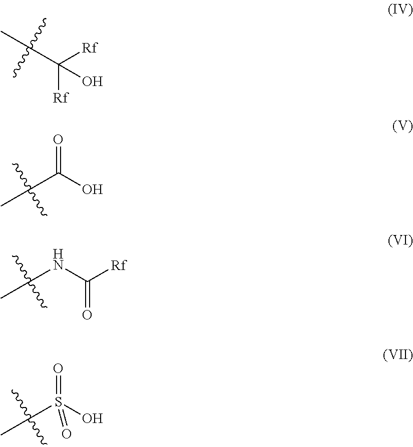

wherein: Rf is independently a partially or completely fluorinated C1-C20 alkyl or a partially or completely fluorinated C6-C20 aryl. Such groups can be present in the polymer, for example, on one or more of the polymer repeating units.

Preferably 50 mol % or more, 80 mol % or more, or 100 mol % of the total polymerized units of the polymer contain aromatic groups. The inclusion of a high content of aromatic groups in the polymer is believed to contribute to improved etch selectivity with respect to the underlayer.

Particularly preferred polymers for the photoresist layer include, for example, the following:

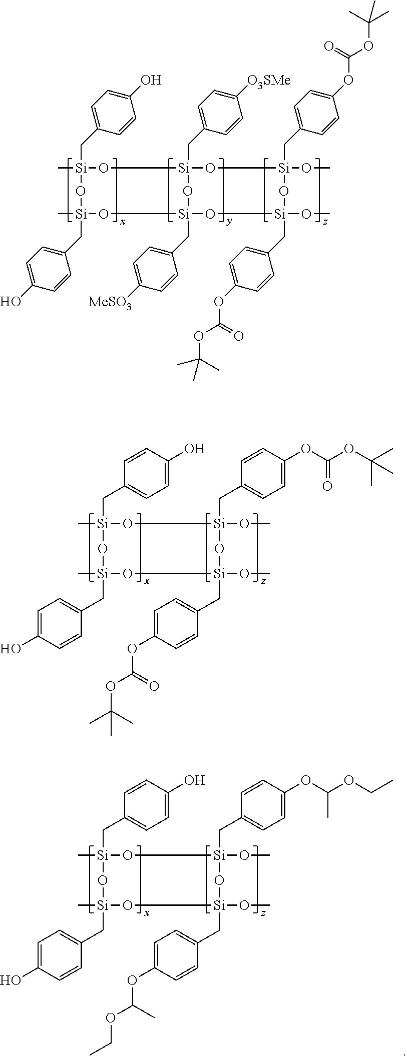

The silicon-containing polymers typically have a molecular weight of 500 to 200,000 Daltons, and preferably from 1000 to 100,000 Daltons. The polymers can readily be prepared by the skilled person. See, for example, Patent Application Publication No. US2003/0099899 A1.

It will be appreciated by those skilled in the art that blends of polymers can be used. For example, more than one silicon-containing polymer may be used in the photoresist compositions. The additional silicon-containing polymers may be, for example, a conventional silicon-containing polymer or an additional polymer as described above. A polymer blend can include blends of the described silicon-containing polymers with non-silicon-containing polymers. In these blends, any ratio of polymers is suitable. The specific ratio will depend upon the particular polymers combined and the characteristics (dissolution rate, etch resistance, photospeed, etc.) desired and are within the ability of one skilled in the art.

The photoresist compositions include one or more photoacid generator (PAG) compounds. Suitable PAGs are known in the art of chemically amplified photoresists and include, for example, non-ionic oximes and various onium cation salts. Onium cations can be substituted or unsubstituted and include, for example, ammonium, phosphonium, arsonium, stibonium, bismuthonium, oxonium, sulfonium, selenonium, telluronium, fluoronium, chloronium, bromonium, iodonium, aminodiazonium, hydrocyanonium, diazenium (RN═N⁺R₂), iminium (R₂C═N⁺R₂), quaternary ammonium having two double-bonded substituents (R═N⁺═R), nitronium (NO₂⁺), bis(trarylphosphine)iminium ((Ar₃P)₂N⁺), tertiary ammonium having one triple-bonded substituent (R≡NH⁺), nitrilium (RC≡NR⁺), diazonium (N≡N⁺R), tertiary ammonium having two partially double-bonded substituents (R [symbol] N⁺H [symbol] R), pyridinium, quaternary ammonium having one triple-bonded substituent and one single-bonded substituent (R≡N⁺R), tertiary oxonium having one triple-bonded substituent (R≡O⁺), nitrosonium (N≡O⁺), tertiary oxonium having two partially double-bonded substituents (R [symbol] O⁺ [symbol] R), pyrylium (C₅H₅O⁺), tertiary sulfonium having one triple-bonded substituent (R≡S⁺), tertiary sulfonium having two partially double-bonded substituents (R [symbol] S⁺ [symbol] R), and thionitrosonium (N≡S⁺). In an embodiment, the onium ion is selected from a substituted or unsubstituted diaryiodonium, or a substituted or unsubstituted triarylsulfonium. Examples of suitable onium salts can be found in U.S. Pat. Nos. 4,442,197, 4,603,101, and 4,624,912.

Suitable photoacid generators are known in the art of chemically amplified photoresists, and include, for example: onium salts, for example, triphenylsulfonium trifluoromethanesulfonate, (p-tert-butoxyphenyl)diphenylsulfonium trifluoromethanesulfonate, tris(p-tert-butoxyphenyl)sulfonium trifluoromethanesulfonate, triphenylsulfonium p-toluenesulfonate; nitrobenzyl derivatives, for example, 2-nitrobenzyl-p-toluenesulfonate, 2,6-dinitrobenzyl-p-toluenesulfonate, and 2,4-dinitrobenzyl-p-toluenesulfonate; sulfonic acid esters, for example, 1,2,3-tris(methanesulfonyloxy)benzene, 1,2,3-tris(trifluoromethanesulfonyloxy)benzene, and 1,2,3-tris(p-toluenesulfonyloxy)benzene; diazomethane derivatives, for example, bis(benzenesulfonyl)diazomethane, bis(p-toluenesulfonyl)diazomethane; glyoxime derivatives, for example, bis-O-(p-toluenesulfonyl)-α-dimethylglyoxime, and bis-O-(n-butanesulfonyl)-α-dimethylglyoxime; sulfonic acid ester derivatives of an N-hydroxyimide compound, for example, N-hydroxysuccinimide methanesulfonic acid ester, N-hydroxysuccinimide trifluoromethanesulfonic acid ester; and halogen-containing triazine compounds, for example, 2-(4-methoxyphenyl)-4,6-bis(trichloromethyl)-1,3,5-triazine, and 2-(4-methoxynaphthyl)-4,6-bis(trichloromethyl)-1,3,5-triazine.

The photoacid generator can having formula G⁺A⁻, wherein A⁻ is an organic anion and G⁺ has formula (A):

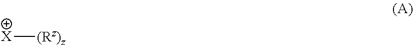

In formula (A), X may be S or I, each R^{z} may be halogenated or non-halogenated, and is independently a C₁₋₃₀ alkyl group; a polycyclic or monocyclic C₃₋₃₀ cycloalkyl group; a polycyclic or monocyclic C₄₋₃₀ aryl group, wherein when X is S, one of the R^{z} groups is optionally attached to one adjacent R^{z} group by a single bond, and z is 2 or 3, and wherein when X is I, z is 2, or when X is S, z is 3.

For example, cation G⁺ may be of formula (B), (C), or (D):

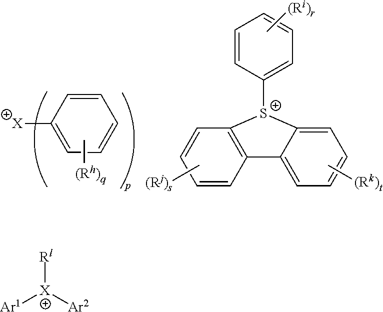

wherein X is I or S; R^{h}, Rⁱ, R^{j}, and R^{k} are unsubstituted or substituted and are each independently hydroxy, nitrile, halogen, C₁₋₃₀ alkyl, C₁₋₃₀ fluoroalkyl, C₃₋₃₀ cycloalkyl, C₁₋₃₀ fluorocycloalkyl, C₁₋₃₀ alkoxy, C₃₋₃₀ alkoxycarbonylalkyl, C₃₋₃₀ alkoxycarbonylalkoxy, C₃₋₃₀ cycloalkoxy, C₅₋₃₀ cycloalkoxycarbonylalkyl, C₅₋₃₀ cycloalkoxycarbonylalkoxy, C₁₋₃₀ fluoroalkoxy, C₃₋₃₀ fluoroalkoxycarbonylalkyl, C₃₋₃₀ fluoroalkoxycarbonylalkoxy, C₃₋₃₀ fluorocycloalkoxy, C₅₋₃₀ fluorocycloalkoxycarbonylalkyl, C₅₋₃₀ fluorocycloalkoxycarbonylalkoxy, C₆₋₃₀ aryl, C₆₋₃₀ fluoroaryl, C₆₋₃₀ aryloxy, or C₆₋₃₀ fluoroaryloxy, each of which is unsubstituted or substituted; A¹ and Ar² are independently C₁₀₋₃₀ fused or singly bonded polycyclic aryl groups; R¹ is a lone pair of electrons where X is I or a C₆₋₂₀ aryl group where X is S; p is an integer of 2 or 3; wherein when X is I, p is 2, and wherein when X is S, p is 3; q and r are each independently an integer from 0 to 5, and t and s are each independently an integer from 0 to 4.

In an embodiment, the PAG is a sulfonium salt represented by formula (6):

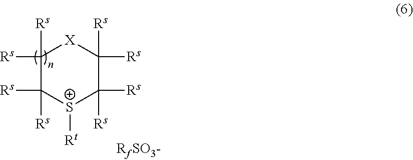

wherein R^{t} may be a substituted or unsubstituted C₂₋₂₀ alkenyl, a substituted or unsubstituted C₃₋₂₀ cycloalkyl, a substituted or unsubstituted C₅₋₃₀ aryl, or a substituted or unsubstituted C₄₋₃₀ heteroaryl. In another embodiment, R^{t} may be a substituted or unsubstituted C₅₋₃₀ aryl or a substituted or unsubstituted C₄₋₃₀ heteroaryl. For example, R^{t} may be a substituted phenyl group. In an embodiment, R^{t} may be a phenyl group substituted with one or more C₁₋₃₀ alkyl or C₃₋₈ cycloalkyl, for example, C₁₋₅ alkyl or C₃₋₆ cycloalkyl. In an embodiment, R^{t} may optionally include an acid-sensitive functional group capable of being hydrolyzed at pH<7.0, for example, a tertiary ester, a tertiary ether, or a tertiary carbonate group.

In formula (6), R^{s} at each occurrence can be the same or different, and may each independently be hydrogen, a halogen, a straight chain or branched C₁₋₂₀ alkyl, a straight chain or branched C₁₋₂₀ fluoroalkyl, a straight chain or branched C₂₋₂₀ alkenyl, a straight chain or branched C₂₋₂₀ fluoroalkenyl, a monocyclic or polycyclic C₃₋₂₀ cycloalkyl, a monocyclic or polycyclic C₃₋₂₀ fluorocycloalkyl, a monocyclic or polycyclic C₃₋₂₀ cycloalkenyl, a monocyclic or polycyclic C₃₋₂₀ fluorocycloalkenyl, a monocyclic or polycyclic C₃₋₂₀ heterocycloalkyl; a monocyclic or polycyclic C₃₋₂₀ heterocycloalkenyl; a monocyclic or polycyclic C₆₋₂₀ aryl, a monocyclic or polycyclic C₆₋₂₀ fluoroaryl, a monocyclic or polycyclic C₄₋₂₀ heteroaryl, or a monocyclic or polycyclic C₄₋₂₀ fluoroheteroaryl, each of which except hydrogen may be substituted or unsubstituted. In an embodiment, each R^{s} may be hydrogen.

Any two of R^{s} groups may be optionally connected via Z′ to form a ring, wherein Z′ may be a single bond or at least one linker selected from —C(═O)—, —S(═O)—, —S(═O)₂—, —C(═O)O—, —C(═O)NR′—, —C(═O)—C(═O)—, —O—, —CH(OH)—, —CH₂—, —S—, and —BR′—, wherein R′ may be hydrogen or a C₁₋₂₀ alkyl group.

Each R^{s} may be optionally substituted, independently from other R^{s} groups, with at least one selected from —OY, —NO₂, —CF₃, —C(═O)—C(═O)—Y, —CH₂OY, —CH₂Y, —SY, —B(Y)ₙ, —C(═O)NRY, —NRC(═O)Y, —(C═O)OY, and —O(C═O)Y, wherein Y is a straight chain or branched C₁₋₂₀ alkyl, a straight chain or branched C₁₋₂₀ fluoroalkyl, a straight chain or branched C₂₋₂₀ alkenyl, a straight chain or branched C₂₋₂₀ fluoroalkenyl, a straight chain or branched C₂₋₂₀ alkynyl, a straight chain or branched C₂₋₂₀ fluoroalkynyl, a C₆₋₂₀ aryl, a C₆₋₂₀ fluoroaryl, or an acid-sensitive functional group capable of being hydrolyzed at pH<7.0, such as a tertiary ester, tertiary ether, or tertiary carbonate group.

In formula (6), X may be a divalent linking group such as O, S, Se, Te, NR″, S═O, S(═O)₂, C═O, (C═O)O, O(C═O), (C═O)NR″, or NR″(C═O), wherein R″ may be hydrogen or a C₁₋₂₀ alkyl. n may be an integer of 0, 1, 2, 3, 4, and 5. In an embodiment, X may be 0.

In formula (6), R_{f}SO₃⁻ is a fluorinated sulfonate anion, wherein R_{f} is a fluorinated group. In an embodiment, R_{f} may be —C(R²⁰)_{y}(R²¹)_{z}, wherein R²⁰ may be independently selected from F and fluorinated methyl, R²¹ may be independently selected from hydrogen, C₁₋₅ linear or branched or cycloalkyl and C₁₋₅ linear or branched or cyclic fluorinated alkyl, y and z may be independently an integer from 0 to 3, provided that the sum of y and z is 3 and at least one of R²⁰ and R²¹ contains fluorine, wherein the total number of carbon atoms in R_{f} may be from 1 to 6. In the formula —C(R²⁰)_{y}(R²¹)_{z}, both R²⁰ and R²¹ are attached to C. Preferably, there is at least one fluorine atom or fluorinated group bonded to the carbon atom at the alpha position with respect to the SO₃⁻ group. In an embodiment, y may be 2, and z may be 1. In these embodiments, each R²⁰ may be F, or one R¹² may be F and the other R²⁰ may be fluorinated methyl. A fluorinated methyl may be monofluoromethyl (—CH₂F), difluoromethyl (—CHF₂), and trifluoromethyl (—CF₃). In another embodiment, R²¹ may be independently selected from C₁₋₅ linear or branched fluorinated alkyl. A fluorinated alkyl may be partially fluorinated or perfluorinated alkyl.

The one or more PAGs are typically present in the photoresist compositions in an amount of from 0.1 to 10 wt % and preferably from 0.1 to 5 wt %, based on total solids.

The photoresist composition further includes a solvent, which can include a single solvent or a mixture of different solvents. The solvent may be an aliphatic hydrocarbon (such as hexane, heptane, and the like), an aromatic hydrocarbon (such as toluene, xylene, and the like), a halogenated hydrocarbon (such as dichloromethane, 1,2-dichloroethane, 1-chlorohexane, and the like), an alcohol (such as methanol, ethanol, 1-propanol, iso-propanol, tert-butanol, 2-methyl-2-butanol, 4-methyl-2-pentanol, and the like), water, an ether (such as diethyl ether, tetrahydrofuran, 1,4-dioxane, anisole, and the like), a ketone (such as acetone, methyl ethyl ketone, methyl iso-butyl ketone, 2-heptanone, cyclohexanone, and the like), an ester (such as ethyl acetate, n-butyl acetate, propylene glycol monomethyl ether acetate (PGMEA), ethyl lactate, hydroxyisobutyrate methyl ester (HBM), ethyl acetoacetate, and the like), a lactone (such as gamma-butyrolactone (GBL), epsilon-caprolactone, and the like), a nitrile (such as acetonitrile, propionitrile, and the like), aa polar aprotic solvent (such as dimethyl sulfoxide, dimethyl formamide, and the like), or a combination thereof. The solvent can be present in the photoresist compositions in an amount of from 40 to 99 wt %, preferably from 40 to 70 wt %, based on the total weight of the photoresist composition.

The photoresist composition may further include one or more optional additives. For example, optional additives may include actinic and contrast dyes, anti-striation agents, plasticizers, speed enhancers, sensitizers, photo-destroyable bases, basic quenchers, surfactants, and the like, or combinations thereof. If present, the optional additives are typically present in the photoresist compositions in an amount of from 0.01 to 10 wt % based on total solids.

Exemplary photo-destroyable bases include, for example, photo-decomposable cations, and preferably those also useful for preparing acid generator compounds, paired with an anion of a weak (pKa>2) acid such as, for example, a C₁₋₂₀ carboxylic acid. Exemplary carboxylic acids include formic acid, acetic acid, propionic acid, tartaric acid, succinic acid, cyclohexylcarboxylic acid, benzoic acid, salicylic acid, and the like.

Exemplary basic quenchers include, for example: linear aliphatic amines such as triisopropanolamine, n-tert-butyldiethanolamine, tris(2-acetoxy-ethyl) amine, 2,2′,2″,2″′-(ethane-1,2-diylbis(azanetriyl))tetraethanol, 2-(dibutylamino)ethanol, and 2,2′,2″-nitrilotriethanol; cyclic aliphatic amines such as 1-(tert-butoxycarbonyl)-4-hydroxypiperidine, tert-butyl 1-pyrrolidinecarboxylate, tert-butyl 2-ethyl-1H-imidazole-1-carboxylate, di-tert-butyl piperazine-1,4-dicarboxylate, and N-(2-acetoxy-ethyl)morpholine; aromatic amines such as pyridine, di-tert-butyl pyridine, and pyridinium; linear and cyclic amides and derivatives thereof such as N,N-bis(2-hydroxyethyl)pivalamide, N,N-diethylacetamide, N¹,N¹,N³,N³-tetrabutylmalonamide, 1-methylazepan-2-one, 1-allylazepan-2-one, and tert-butyl 1,3-dihydroxy-2-(hydroxymethyl)propan-2-ylcarbamate; ammonium salts such as quaternary ammonium salts of sulfonates, sulfamates, carboxylates, and phosphonates; imines such as primary and secondary aldimines and ketimines; diazines such as optionally substituted pyrazine, piperazine, and phenazine; diazoles such as optionally substituted pyrazole, thiadiazole, and imidazole; and optionally substituted pyrrolidones such as 2-pyrrolidone and cyclohexyl pyrrolidine.

Exemplary surfactants include fluorinated and non-fluorinated surfactants and can be ionic or non-ionic, with non-ionic surfactants being preferable. Exemplary fluorinated non-ionic surfactants include perfluoro C₄ surfactants such as FC-4430 and FC-4432 surfactants, available from 3M Corporation; and fluorodiols such as POLYFOX PF-636, PF-6320, PF-656, and PF-6520 fluorosurfactants from Omnova. In an embodiment, the photoresist composition further includes a surfactant polymer including a fluorine-containing repeating unit.

The photoimageable compositions of the present invention may be readily prepared by those skilled in the art. For example, a photoresist composition of the invention can be prepared by dissolving the components of the photoresist, i.e., polymer binder and photoactive component, in a suitable solvent. Such suitable solvents include, but are not limited to: ethyl lactate, ethylene glycol monomethyl ether, ethylene glycol monomethyl ether acetate, propylene glycol monomethyl ether, propylene glycol monomethyl ether acetate, 3-ethoxyethyl propionate, 2-heptanone, γ-butyrolactone, and mixtures thereof.

Typically, the solids content of the photoresist composition varies from about 5 to about 35 percent by weight, based on the total weight of the composition. The polymer and photoactive components should be present in amounts sufficient to provide a film coating layer and formation of good quality latent and relief images.

The following non-limiting examples are illustrative of the invention.

### EXAMPLES

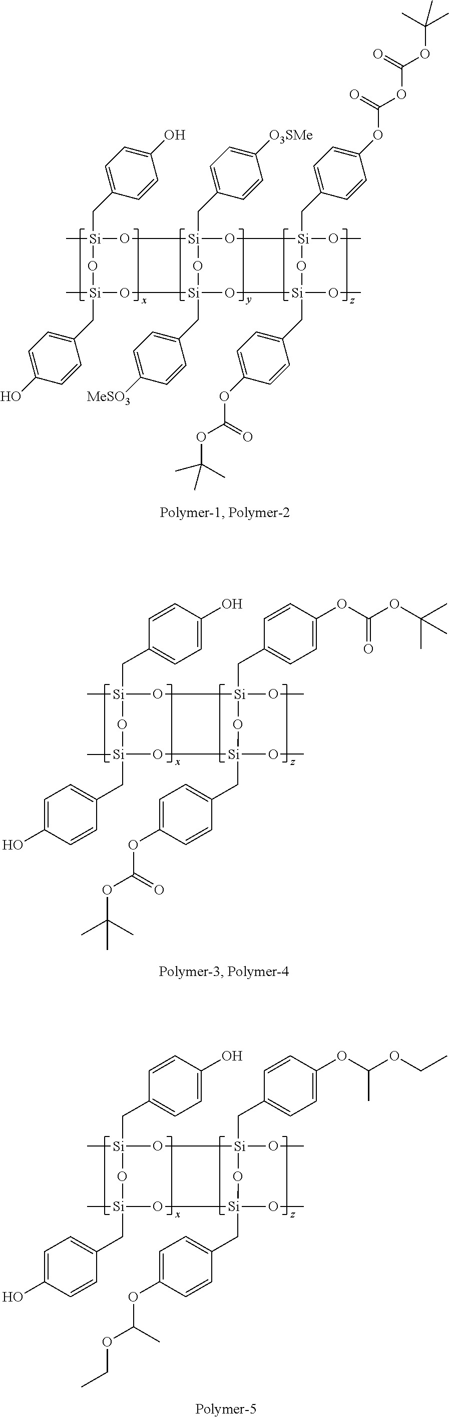

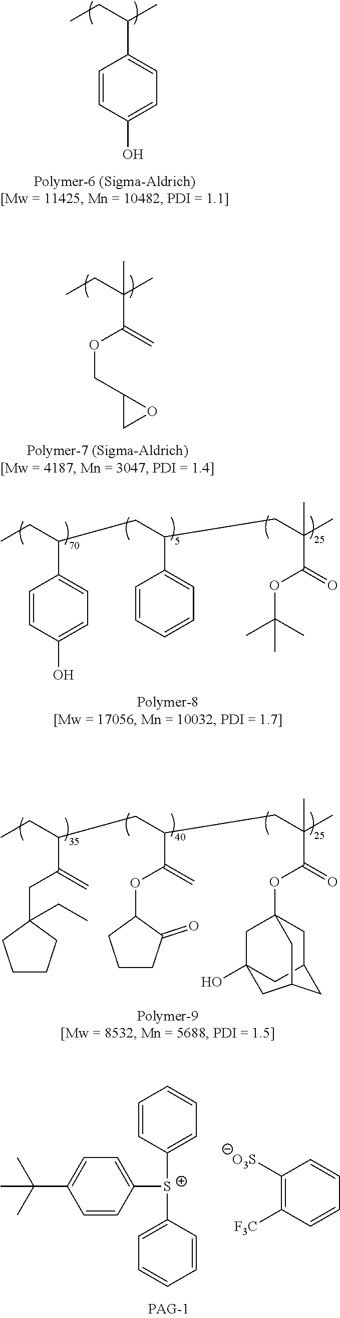

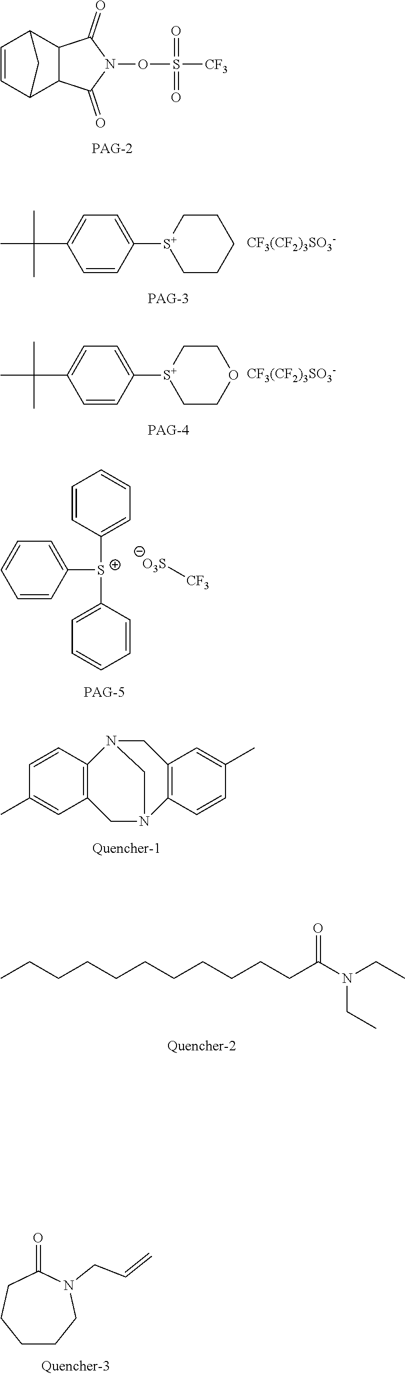

### Photoresist Polymer Synthesis

### Example 1

Poly(4-hydroxybenzyl silsesquioxane) (254.7 g) was dissolved in 1000 mL dry acetone under nitrogen atmosphere in a dried 3 L flask (reactor). Methanesulfonyl chloride (23.8 g) was added and the reactor was cooled to 15° C. A solution of distilled triethylamine (21.9 g) and acetone (22 g) was gradually added dropwise over 20-30 minutes, maintaining a reaction temperature of less than 30° C. Stirring was continued for 3 hours, at which time the solution was added dropwise over 2 hours to 32 L of water, precipitating the polymer. The polymer was then collected by suction filtration, and suspended in 8 L of water with stirring at room temperature for 18 hours. The solid was then collected by suction filtration, washed with water until the effluent was pH neutral, air-dried for 48 hours, and then dried in vacuo for 24 hours at 70° C. to yield an off-white polymer having a composition of 91 mol % hydroxybenzylsilsesquioxane/9 mol % mesylated benzylsilsesquioxane.

The obtained mesylated polymer (163.1 g) was dissolved in 750 mL dry acetone under nitrogen atmosphere in a dried 2 L flask (reactor). Di-t-butyl dicarbonate (65.5 g) was dissolved in 300 mL acetone and added to the reactor, followed by N,N-dimethylaminopyridine (DMAP, 0.25 g) dissolved in 2 mL acetone, and the resulting pale orange solution was stirred at 25° C. for 25 hours. The acetone solution of polymer was added dropwise over 2 hours to 24 L of water, precipitating the polymer. The polymer was then collected by suction filtration, washed with water, and dried in vacuo at 20° C. to constant weight (ca. 72 hours) to yield an off-white polymer (Polymer-1) [(x/y/z=66/9/25), Mw=8559, Mn=5038, PDI=1.7].

### Example 2

Polymer-2 was prepared using a similar procedure to that described in Example 1 [(x/y/z=56/9/35), Mw=7637, Mn=4898, PDI=1.6].

### Examples 3 and 4

Polymer-3 and Polymer-4 were prepared using a similar procedure to that described in Example 1: Polymer-3 [(x/z=65/35), Mw=7850, Mn=4925, PDI=1.6]; Polymer-4 [(x/z=55/45), Mw=8001, Mn=4922, PDI=1.6].

### Example 5

Poly(4-hydroxybenzyl silsesquioxane) (61.2 g) was dissolved in 750 mL 1-methoxy-2-propyl acetate (PMA). The solution was distilled under vacuum, residual water was reduced to <0.07 wt %, and the concentration was increased to 30.61 wt % polymer in PMA (as calculated by mass balance). This distillatively dried polymer solution was then transferred to a 250 mL reaction flask under nitrogen. Trifluoroacetic acid (150 mg) in 1 mL PMA was added, followed by distilled ethyl vinyl ether (15.32 g), and the resulting solution was stirred for 24 hours at ambient temperature. AmberLite™ IRA-67 Ion Exchange Resin (25 g, DuPont Water Solutions) was washed sequentially with water, acetone, and PMA, and was then added to the reaction flask to neutralize the acidic catalyst. The suspension was stirred for 2 hours, followed by removal of the ion exchange resin by filtration to yield Polymer-5 [(x/z=67/33), Mw=7425, Mn=4709, PDI=1.6].

### Si-Containing Photoresist Composition Preparation

### Examples 6-11

Silicon-containing photoresist compositions were prepared by combining and mixing the components in the amounts shown in Table 1. The mixtures were then filtered with a 0.2 micron PTFE syringe filter, resulting in silicon-containing photoresist compositions SiPR-1˜SiPR-6.

TABLE 1

| | Ex. 6 | Ex. 7 | Ex. 8 | Ex. 9 | Ex. 10 | Ex. 11 |
|---|---|---|---|---|---|---|
| Component | SiPR-1 | SiPR-2 | SiPR-3 | SiPR-4 | SiPR-5 | SiPR-6 |
| Polymer A | Polymer-1 | Polymer-1 | Polymer-1 | Polymer-1 | Polymer-3 | Polymer-5 |
| | (10.71) | (10.71) | (10.71) | (11.1) | (10.95) | (14.61) |
| Polymer B | Polymer-2 | Polymer-2 | Polymer-2 | Polymer-2 | Polymer-4 | |
| | (4.78) | (4.78) | (4.78) | (4.76) | (3.65) | |
| PAG A | PAG-1 | PAG-1 | PAG-1 | PAG-1 | PAG-1 | PAG-1 |
| | (0.41) | (0.41) | (0.41) | (0.41) | (0.38) | (0.38) |
| PAG B | PAG-2 | PAG-2 | PAG-3 | PAG-4 | PAG-2 | PAG-2 |
| | (1.01) | (1.01) | (1.01) | (1.01) | (0.93) | (0.93) |
| Quencher | Quencher-1 | Quencher-2 | Quencher-2 | Quencher-3 | Quencher-1 | Quencher-1 |
| | (0.06) | (0.06) | (0.06) | (0.06) | (0.06) | (0.06) |
| SLA | SLA-1 | SLA-1 | SLA-1 | SLA-1 | SLA-1 | SLA-1 |
| | (0.03) | (0.03) | (0.03) | (0.03) | (0.03) | (0.03) |
| Solvent A | Solvent-1 | Solvent-1 | Solvent-1 | Solvent-1 | Solvent-1 | Solvent-1 |
| | (74.7) | (74.7) | (74.7) | (57.8) | (75.6) | (67.2) |
| Solvent B | Solvent-2 | Solvent-2 | Solvent-2 | Solvent-3 | Solvent-2 | Solvent-3 |
| | (8.3) | (8.3) | (8.3) | (8.3) | (8.4) | (16.8) |
| Solvent C | | | | Solvent-2 | | |
| | | | | (16.5) | | |

SLA-1 = POLYFOX PF-656 surfactant (Omnova Solutions Inc.); Solvent-1 = Propylene glycol methyl ether acetate (PGMEA); Solvent-2 = Ethyl lactate; Solvent-3 = Propylene glycol methyl ether (PGME); Solvent-4 = gamma-butyrolactone (GBL).

### Comparative (Thick KrF) Photoresist Composition Preparation

### Example 12 (Comparative)

15.787 g of Polymer-8, 3.947 g of Polymer-9, 0.010 g of SLA-1, and 0.007 g of Quencher-3 were dissolved in 24.000 g of Solvent-1. To this mixture was added 0.200 g of PAG-3 and 0.050 g of PAG-5 which were dissolved in 4.500 g of Solvent-3. 1.500 g of Solvent-4 was added to the resulting mixture. The final mixture was rolled on a roller for 12 hours and then filtered through a Teflon filter having a 1 micron pore size to yield photoresist TPR-1.

### Underlayer Composition Preparation

### Example 13

26.587 g of Polymer-6, 11.349 g of Polymer-7, and 0.019 g of SLA-1 were dissolved in a mixture of 55.845 g of Solvent-1 and 6.200 g of Solvent-2. The mixture was rolled on a roller for 12 hours and then filtered through a Teflon filter having a 1 micron pore size to yield underlayer composition UL-1.

### Lithographic Evaluation

### Examples 14-21

200 mm silicon wafers were spin-coated with UL-1 underlayer composition using a TEL MARK-8 (Tokyo Electron) coating track. The wafers were baked at 275° C. for 90 seconds to yield a film having a thickness of from 5 to 12 microns. The wafers were coated with a respective silicon-containing photoresist composition and baked at 90° C. for 90 seconds to provide silicon photoresist layers having a thickness of 0.5 microns. The photoresist-coated wafers were exposed to KrF radiation (248 nm) using an ASML300 stepper and a numerical aperture of 0.52, with a binary mask having a 5 micron isolated trench pattern. The exposed wafers were post-exposure baked at 90° C. for 90 seconds and developed for 45 seconds with CD-26 0.26N tetramethylammonium hydroxide solution (DuPont Electronics & Imaging) to form resist patterns. Top-view scanning electron microscopy (SEM) images were captured using a Hitachi 9300 CD-SEM. E_{size} was determined as the exposure dose to print a 5 micron isolated trench pattern on a wafer. CD measurements for one of the wafers were taken and CD Uniformity (CDU) was calculated as the standard deviation of CDs taken at 33 locations on the wafer. The results are shown in Table 2.

### Example 22 (Comparative)

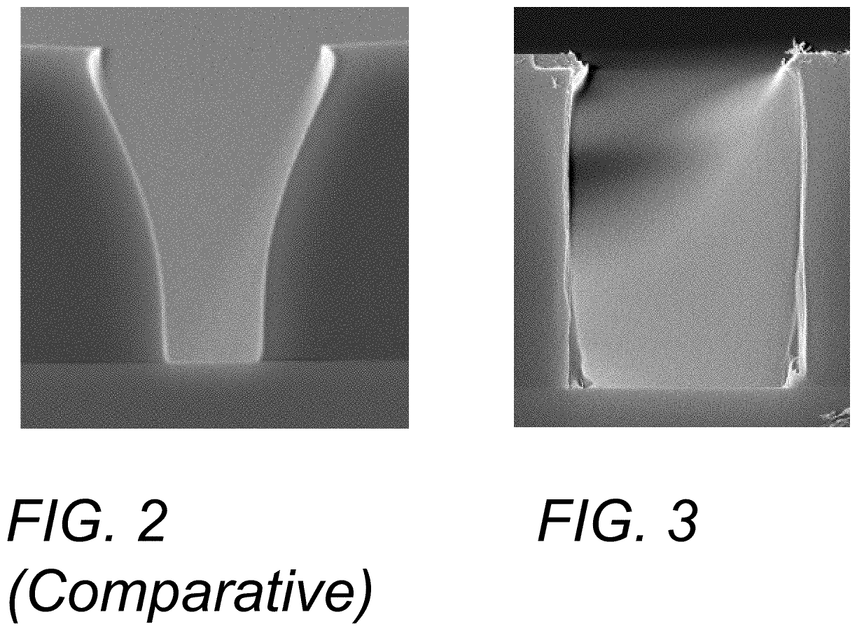

200 mm silicon wafers were primed with HMDS at 180° C. for 60 seconds and then spin-coated with the KrF Photoresist of Example 12 (TPR-1) using a TEL MARK-8 (Tokyo Electron) coating track. The wafers were baked at 150° C. for 70 seconds to provide a photoresist layer having a thickness of 13 microns. The photoresist-coated wafers were exposed to KrF radiation (248 nm) using an ASML300 stepper and a numerical aperture of 0.52, with a binary mask having a 5 micron isolated trench pattern. The exposed wafers were post-exposure baked at 110° C. for 50 seconds and developed for 45 seconds with CD-26 0.26N tetramethylammonium hydroxide solution (DuPont Electronics & Imaging) to form resist patterns. Top-view scanning electron microscopy (SEM) images were captured and E_{size} and CDU were determined as described above. The results are shown in Table 2. Cross-sectional SEM images were captured using an AMRAY-3304 SEM, with a representative image being shown in FIG. 2.

TABLE 2

| | Underlayer | | Photoresist | | |
|---|---|---|---|---|---|
| | Thickness | | Thickness | E_{size} | CDU |
| Example | (μm) | Photoresist | (μm) | (mJ/cm²) | (nm) |
| Ex. 14 | 12 | SiPR-1 | 0.5 | 40.4 | * |
| Ex. 15 | 12 | SiPR-2 | 0.5 | 35.1 | * |
| Ex. 16 | 12 | SiPR-3 | 0.5 | 32 | * |
| Ex. 17 | 12 | SiPR-4 | 0.5 | 33 | * |
| Ex. 18 | 12 | SiPR-5 | 0.5 | 42 | * |
| Ex. 19 | 12 | SiPR-6 | 0.5 | 28 | * |
| Ex. 20 | 5 | SiPR-1 | 0.5 | 36.7 | * |
| Ex. 21 | 10 | SiPR-1 | 0.5 | 38.3 | 81 |
| Ex. 22 | — | TPR-1 | 13 | 90 | 166 |
| (Comp.) | | | | | |

* CDU not measured.

The E_{size} results indicate that the silicon-containing photoresists in Examples 14-21 provided significantly faster photospeeds (lower E_{size} values) than that of the comparative photoresist of Example 22. In addition, the silicon-containing photoresist in Example 21 resulted in significantly improved CDU as compared with the comparative photoresist of Example 22.

### Pattern Transfer Evaluation

### Example 23

An underlayer-coated silicon wafer having silicon-containing resist patterns formed in Example 21 was loaded into the etch chamber of a Plasma-Therm 790 etching system. O₂ plasma etching was conducted on the wafers under the following conditions: Pressure=15 mTorr; Power=180 W; O₂ Gas Flow=90 sccm; and Etch Time=80 minutes. Cross-sectional SEM images of the post-etched trench pattern were captured using an AMRAY-3304 SEM, with a representative image being shown in FIG. 3.

Comparing the SEM images of FIGS. 2 and 3, it can be seen that a much straighter vertical profile resulted for the silicon-containing photoresist/organic underlayer structure formed in Example 23 (FIG. 3) than for the photo-imaged thick photoresist layer pattern of Example 22 (FIG. 2).

1. A pattern formation method, comprising:
(a) forming an underlayer on a substrate, wherein the underlayer has a thickness of 5 microns or more;
(b) forming a photoresist layer on the underlayer, wherein the photoresist layer is formed from a photoresist composition comprising a silicon-containing polymer, a photoacid generator, and a solvent, wherein the silicon-containing polymer comprises as polymerized units a monomer of formula (I): 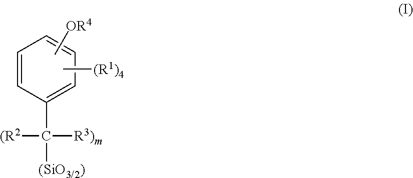
wherein: R¹ is independently chosen from H, F, OH, C1-C6 alkyl, C1-C6 haloalkyl, C1-C6 hydroxy-haloalkyl, C1-C6 alkoxy, or C1-C6 haloalkoxy; R² is independently chosen from H or F; R³ is independently chosen from H, F, CH₃, CF₃, CHF₂, or CH₂F; R⁴ comprises an acid cleavable group; and m is an integer from 0 to 2;
(c) patternwise exposing the photoresist layer to activating radiation;
(d) developing the exposed photoresist layer to form a photoresist pattern; and
(f) transferring the pattern of the photoresist pattern into the underlayer using the photoresist pattern as an etch mask.

2. The pattern formation method of claim 1, wherein: R⁴ is independently chosen from —C(O)OC(R⁵)₃ or —C(R⁶)₂OR⁷, wherein R⁵ is independently chosen from H, C1-C20 alkyl, C3-C20 heteroalkyl, C6-C20 aryl, C4-C20 heteroaryl, or C7-C20 aryloxyalkyl, each of which except hydrogen is substituted or unsubstituted, and two or more R⁵ together optionally form a ring; R⁶ is independently chosen from H, C1-C12 alkyl, C3-C12 heteroalkyl, C6-C14 aryl, or C4-C14 heteroaryl, each of which except hydrogen is substituted or unsubstituted, and two R⁶ together optionally form a ring; R⁷ is chosen from H, C1-C20 alkyl, C3-C20 heteroalkyl, C6-C20 aryl, C4-C20 heteroaryl, or C7-C20 aryloxyalkyl, each of which except hydrogen is substituted or unsubstituted.

3. The pattern formation method of claim 1, wherein the silicon-containing polymer further comprise as polymerized units one or more monomers of formula (II): 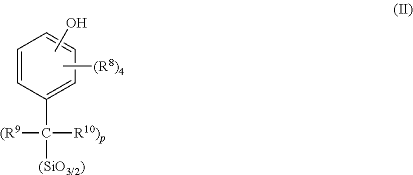
wherein: R⁸ is independently chosen from H, F, OH, C1-C6 alkyl, C1-C6 haloalkyl, C1-C6 hydroxy-haloalkyl, C1-C6 alkoxy, or C1-C6 haloalkoxy; R⁹ is independently chosen from H or F; R¹⁰ is independently chosen from H, F, CH₃, CF₃, CHF₂, or CH₂F; and p is an integer from 0 to 2.

4. The pattern formation method of claim 1, wherein the silicon-containing polymer further comprises as polymerized units a monomer of formula (III):
(R¹¹SiO_{3/2}) (III)
wherein: R¹¹ is chosen from C1-C12 alkyl, C2-C6 alkenyl, vinyl, each of which may be substituted or unsubstituted, 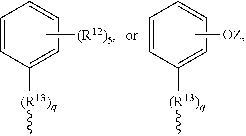
wherein: each R¹² is independently chosen from H, F, C1-C6 alkyl, C1-C6 alkoxy, C1-C6 haloalkyl, C1-C6 hydroxy-haloalkyl, C1-C6 haloalkoxy; R¹³ is C1-C5 alkylene; Z is chosen from —S(O₂)R¹⁴, wherein R¹⁴ is chosen from C1-C6 alky or C6-C15 aryl; q is 0 or 1; and the wavy line is a covalent bond to a Si atom in formula (III).

5. The pattern formation method of claim 1, wherein the silicon-containing polymer comprises one or more groups chosen from formulas (IV), (V), (VI), or (VII): 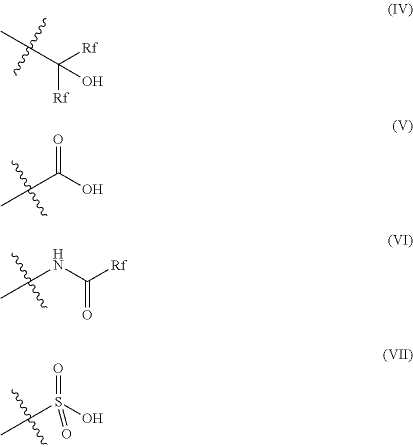
wherein: Rf is independently a partially or completely fluorinated C1-C20 alkyl or a partially or completely fluorinated C6-C20 aryl.

6. The pattern formation method of claim 1, wherein the underlayer is formed from an underlayer composition comprising an organic polymer, a crosslinker, and a solvent.

7. The pattern formation method of claim 6, wherein the organic polymer is a phenolic polymer.

8. The pattern formation method of claim 1, wherein the underlayer has a thickness of 10 microns or more.

9. The pattern formation method of claim 1, wherein (a) forming the underlayer on the substrate comprises:
(a1) coating an organic underlayer composition on the substrate;
(a2) drying the coated underlayer composition; and
(a3) repeating (a1) and (a2) one or more additional times to form the underlayer.

10. The pattern formation method of claim 1, further comprising, in sequence:
(g) after transferring the pattern of the photoresist pattern into the underlayer, transferring the pattern of the underlayer into the substrate to form a first etched substrate region;
(h) trimming the underlayer to expose a surface of the substrate adjacent to the first etched substrate region; and
(i) transferring the pattern of the trimmed underlayer into the exposed surface of the substrate while simultaneously further etching the first etched substrate region.

11. The pattern formation method of claim 1, wherein the method forms a staircase pattern comprising a plurality of stairs in the substrate.
